(19) United States
(12) Patent Application Publication
(10) Pub. No.: US 2015/0105010 A1
(43) Pub. Date: Apr. 16, 2015

(54) Fan Controller and Server System with the Fan controller

(71) Applicants: INVENTEC CORPORATION, Taipei City (TW); Inventec (Pudong) Technology Corporation, Shanghai (CN)

(72) Inventor: Xiao-Bing ZOU, SHANGHAI (CN)

(73) Assignees: INVENTEC CORPORATION, Taipei City (TW); Inventec (Pudong) Technology Corporation, Shanghai (CN)

(21) Appl. No.: 14/149,836

(22) Filed: Jan. 8, 2014

(30) Foreign Application Priority Data
Oct. 12, 2013 (CN) 201310475932.7

(51) Int. Cl. H05K 7/20; F04D 19/00; F04D 27/00

(52) U.S. Cl. CPC H05K 7/20836; F04D 27/001; F04D 19/002; H05K 7/20718
USPC 454/184; 700/275

(57) ABSTRACT

The fan controller controls a plurality of fans in a server system according to a fan control signal. The fan controller comprises a control unit, a current monitor, a power supply module, current sampling units and switches. The power supply module transfers power to the fans through branch power lines respectively. The current sampling units and switches are disposed on the branch power lines respectively. The control unit switches the switches and the current sampling units sample current signals in the branch power lines respectively. When the current monitor monitors one of the current signals being over a threshold value, the current monitor issues an over-current signal to the control unit to turn off the corresponding switch to cut off the power supplied to the corresponding fan by the power supply module.

### RELATED APPLICATIONS

This application claims priority to Chinese Application Serial Number 201310475932.7, filed Oct. 12, 2013, which is herein incorporated by reference.

### BACKGROUND

1. Field of Invention

The invention relates to a fan controller, and particularly relates to a fan controller in a server system.

2. Description of Related Art

Thermal control is important to keep a stable server. Typically, a server includes a fan to perform the thermal control. Therefore, when multiple servers are grouped together to perform calculation work, it is required for fans equal to the servers in amount to realize thermal control. Particularly, in a Microserver array usage, there are twelve CPU boards in a 2U server cabinet, in which each CPU board includes four system-on-chips respectively working as a server. To perform the thermal control in the server cabinet, a fan control system is typically used to control the fans. However, if the fan control system fails to properly work, the fans can no longer function to thermally control the server cabinet, which causes damage for the server.

Therefore, a fan controller can solve the above problem is needed.

### SUMMARY

Accordingly, the present invention provides a fan controller for a server system to improve the reliability of thermal control.

An aspect of the invention provides a fan controller. The fan controller controls a plurality of fans in a server system according to a fan control signal. The fan controller comprises a control unit, a current monitor, a power supply module, current sampling units and switches. The current monitor couples with the control unit. The power supply module transfers power to the fans through branch power lines respectively. The current sampling units and switches are disposed on the branch power lines respectively. The current sampling units couple with the current monitor. The switches couple with the control unit. The control unit switches the switches and the current sampling units sample current signals in the branch power lines respectively. When the current monitor monitors one of the current signals being over a threshold value, the current monitor issues an over-current signal to the control unit to turn off the corresponding switch to cut off the power supplied to the corresponding fan by the power supply module.

In an embodiment, the switches are transistors, the source electrodes and the drain electrodes of the transistors are coupled to the branch power lines respectively and the gate electrodes of the transistors are coupled to the control unit.

In an embodiment, the fans correspond to printed circuit boards respectively. Indicator lights are disposed on the printed circuit boards respectively. When one of the fans is broken, the control unit generates a failure signal to turn on a corresponding indicator light.

In an embodiment, the control unit further couples with a thermal unit, the control unit generates a fan control signal to control the fans according to a real-time temperature of the thermal unit. The control unit has a fan control table, the fan control table records the relationship between temperatures of the thermal unit and set rotation speeds of fans, wherein the control unit gets a set rotation speed according to the real-time temperature of the thermal unit from the fan control table, and the control unit generates the fan control signal according to the set rotation speed.

In an embodiment, the fans generate rotation speed feedback signals to the control unit, the control unit determines rotation speeds of the fans according to the rotation speed feedback signals, wherein when a rotation speed of a fan is not equal to a set rotation speed, the fan is determined to be broken. When the control unit still receives the rotation speed feedback signals after the control unit turns off the switches, the fan controller is determined to be broken.

In an embodiment, the control unit further performs a self detection process, when the control unit can not read the fan control table, the fan controller is determined to be broken.

Another aspect of the invention provides a server system. The server system comprises a fan backplate, a server array, a substrate and a fan controller. The fan backplate has fans. The server array has calculation nodes. The substrate has a multiplexer. The calculation nodes couple with the multiplexer. The fan controller couples with the calculation nodes through the multiplexer. The fan controller generates a fan control signal to control rotation speeds of the fans according to real-time temperatures of the calculation nodes. The fan controller comprises a control unit, a current monitor, a power supply module, current sampling units and switches. The current monitor couples with the control unit. The power supply module transfers power to the fans through branch power lines respectively. The current sampling units and switches are disposed on the branch power lines respectively. The current sampling units couple with the current monitor. The switches couple with the control unit. The control unit switches the switches and the current sampling units sample current signals in the branch power lines respectively, When the current monitor monitors one of the current signals being over a threshold value, the current monitor issues an over-current signal to the control unit to turn off the corresponding switch to cut off the power supplied to the corresponding fan by the power supply module.

In an embodiment, the fan backplate further comprises a first connector and a second connector, the fans receive the fan control signal through the first connector and the fans couple with the power supply module through the second connector.

In view of the above, the server system includes a backup fan controller. When one of the fan controllers is broken, the backup fan controller is triggered to control the fans. Therefore, the thermal damage for the server system is prevented. Moreover, a hot-plugging method is used to replace the fan controllers or the fans. Therefore, it is not necessary to power off the server system to replace the fan controllers or fans.

### BRIEF DESCRIPTION OF THE DRAWINGS

FIG. 1 illustrates a schematic view of a server system according to an embodiment of the invention.

FIG. 2 illustrates a schematic view of a first fan controller according to an embodiment of the invention.

### DETAILED DESCRIPTION

Specific embodiments of the invention are described in details as follows with reference to the accompanying drawings, wherein throughout the following description and drawings, the same reference numerals refer to the same or similar elements and are omitted when the same or similar elements are stated repeatedly.

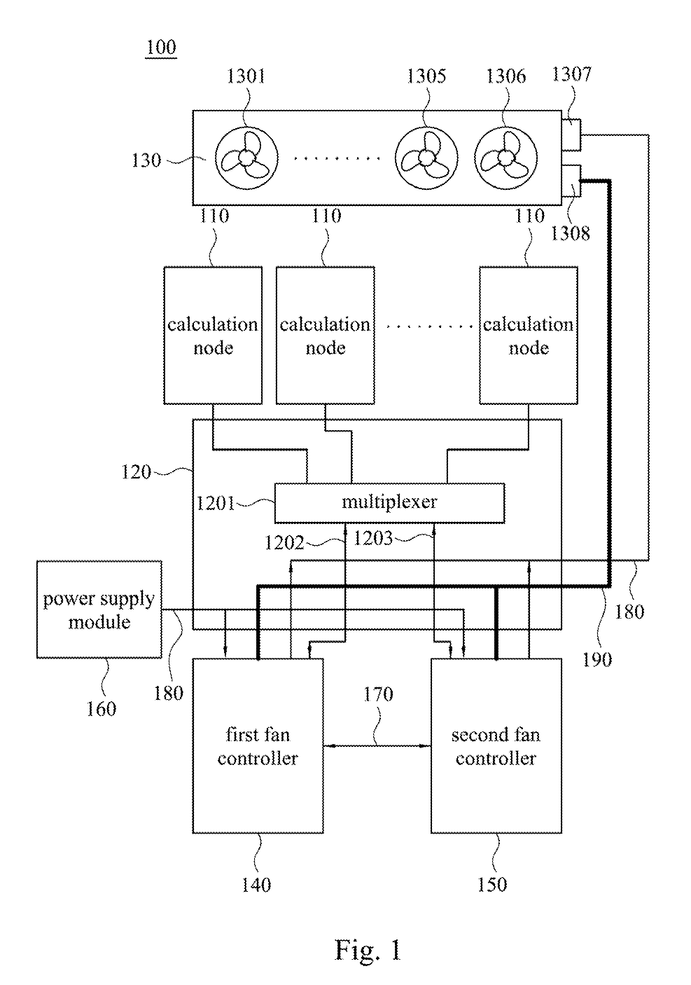

FIG. 1 illustrates a schematic view of a server system according to an embodiment of the invention. A server system 100 of the invention includes a server array with calculation nodes 110, a substrate 120, a fan backplate 130, a first controller 130, a second fan controller 150 and a power supply module 160. The calculation nodes 110 couple with the substrate 120 respectively. The substrate 120 selects one of the calculation nodes 110 through the multiplexer 1201. The substrate communicates with the selected calculation node to get its data. The data is transferred to the first fan controller 140 and the second fan controller 150 through the I2C bus 1202 and the I2C bus 1203 respectively. Fans 1301-1306 are disposed on the fan backplate 130. The power supply module 160 supplies voltage signal to the first fan controller 140 and the second fan controller 150 through the power line 180. Then, the voltage signal is transferred to the fans 1301-1306 on the fan backplate 130 by the first fan controller 140 and the second fan controller 150 through the power line 180. For example, a voltage signal with 12 volts is transferred to the fans 1301-1306 on the fan backplate 130. In an embodiment, the first fan controller 140 or the second fan controller 150 generates a control signal according to the data of one of the calculation nodes 110 selected by the multiplexer 1201 in the substrate 120. This control signal controls the rotation speed of the fans 1301-1306 on the fan backplate 130 through a signal line 190. The power line 180 is connected to the connector 1307 disposed on the fan backplate 130. The signal line 190 is connected to the connector 1308 disposed on the fan backplate 130. Because no other electrical devices are disposed on the fan backplate 130, the reliability of the fan backplate 130 is much improved.

In this embodiment, the first fan controller 140 communicates with the second fan controller 150 through a serial general purpose input/output, SGPIO, bus 170. The first fan controller 140 and the second fan controller 150 do not be operated at the same time. The first fan controller 140 and the second fan controller 150 form a redundancy system. When the first fan controller 140 is used to control the rotation speed of the fans 1301-1306, the second fan controller 150 is in a standby state. In contrast, when the second fan controller 150 is used to control the rotation speed of the fans 1301-1306, the first fan controller 140 is in a standby state. In other word, the server system includes a backup fan controller. When one of the two fan controllers is broken, another fan controller is triggered to control the fans 1301-1306. Therefore, the thermal damage for the server system is prevented. On the other hand, a hot-plugging method is used to replace the first fan controller 140 and the second fan controller 150 in the server system. Therefore, it is not necessary to power off the server system to replace the fan controllers.

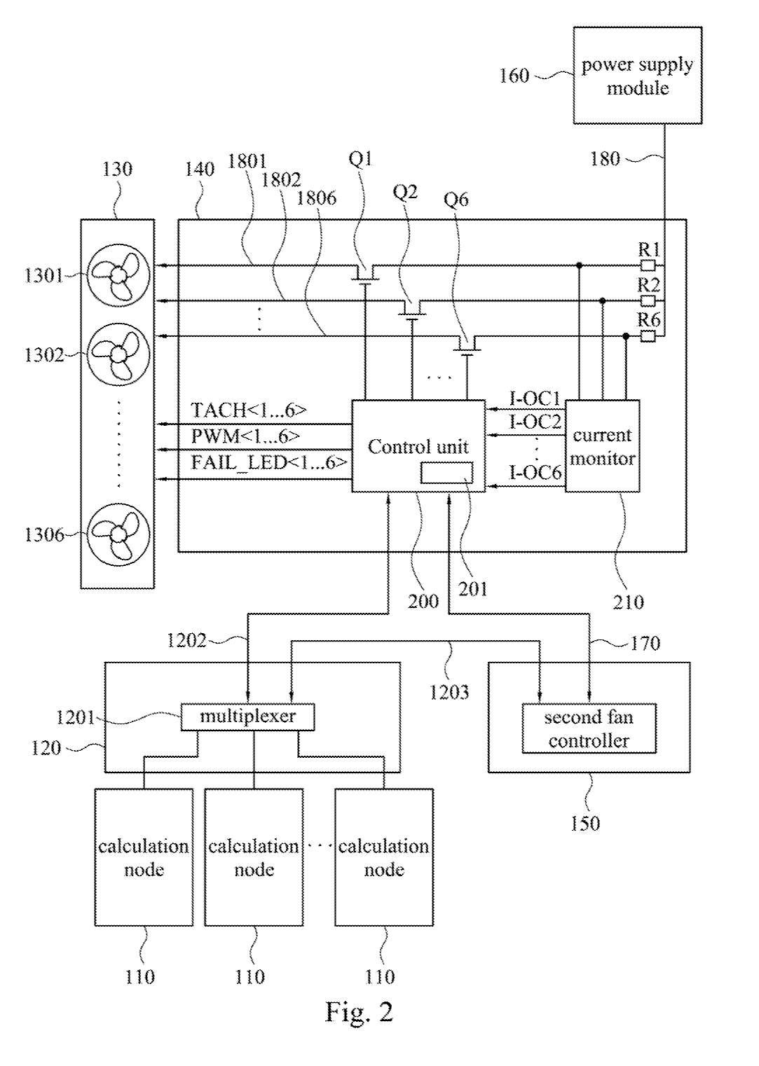

FIG. 2 illustrates a schematic view of a first controller according to an embodiment of the invention. The first fan controller 140 and the second fan controller 150 have a same structure. In this embodiment, the first controller 140 is used to control fans 1301-1306 on the fan backplate 130. The first fan controller 140 comprises a control unit 200, a current monitor 210 and a power supply module 160. Because the first fan controller controls fans 1301-1306 at the same time, the power line 180 from the power supply module 160 are separated to six branch power lines 1801-1806 to transfer voltage signal to the fans 1301-1306 respectively. Six current sampling units R1-R6 and six switches Q1-Q6 are disposed on the branch power lines 1801-1806 respectively. Accordingly, after the first fan controller 140 receives the voltage signal from the power supply module 160, the voltage signal is transferred to the fans 1301-1306 through the current sampling units R1-R6 and switches Q1-Q6 respectively. Current sampling units R1-R6 couple with the current monitor 210. Switches Q1-Q6 couple with the control unit 200. The control unit 200 switches the switches Q1-Q6. The current sampling units R1-R6 sample the current signals in the branch power lines 1801-1806 respectively for the current monitor 210. The current monitor 210 monitors the voltage supplied to the fans 1301-1306 respectively according to the current signals gathered by the current sampling units R1-R6. When the current monitor 210 monitors one of the current signals being over a threshold value, a corresponding over-current signal I_OC1-I_OC6 is issued by the current monitor 210 to the control unit 200 to turn-off the corresponding switch Q1-Q6 to cut off the power supplied to the fan by the power supply module 160. Therefore, over-current damage to fans 1301-1306 is prevented. On the other hand, when one of the fans 1301-1306 is broken because of over-current damage, the control unit 200 generates a failure signal FAIL_LED to turn on a corresponding indicator light, such as a LED, to inform the operator the fan is broken. In this embodiment, a hot plugging method is used to replace the broken fan. The current sampling units R1-R6 are resistors. The switches Q1˜Q6 are transistors, such as P-type transistors. The source electrodes and the drain electrodes of the transistors are coupled to the branch power lines 1801-1806 respectively. The gate electrodes of the transistors are coupled to the control unit 200. Printed circuit boards are embedded in shells of fans 1301-1306 respectively. LEDs are disposed on the printed circuit boards. When a fan is broken, a corresponding LED is turned on to inform the operator.

The control unit 200 couples with the multiplexer 1201 in the substrate 120 through the I2C bus 1202 to communicate with the calculation nodes 110. The control unit 200 gets temperature data in real time of thermal units in the calculation nodes 110. According to the real time temperature data, the control unit 200 gathers fan control signals PWM <1 . . . 6> from a fan control table. The fan control table is stored in a memory unit 201 to record the relationship between the temperatures and the rotation speeds. Therefore, each fan control signal PWM<1 . . . 6> can control a fan to rotate in a set rotation speed. Accordingly, the fan control signals PWM <1 . . . 6> are transferred to the fans 1301-1306 from the control unit 200 to control the fans 1301-1306 to rotate according to the set rotation speeds. On the other hand, fans 1301-1306 generate rotation speed feedback signals TACH<1 . . . 6> to the control unit 200. According to the rotation speed feedback signals TACH<1 . . . 6>, the control unit 200 can know the rotation states of fans 1301-1306. In other words, when the rotation speed feedback signals TACH<1 . . . 6> indicate that the rotation speeds of some fans are not equal to the set rotation speeds, the control unit 200 can determine that these fans are broken. Then, the failure signals FAIL_LED are issued by the control unit 200 to turn on corresponding LEDs to inform the operator the fans are broken. At the same time, the corresponding switches Q1-Q6 are turned off to cut off the power supply module 160 to supply power to the fans. The failure signals FAIL_LED, the rotation speed feedback signals TACH<1 . . . 6> and the fan control signals PWM <1 . . . 6> are transferred to the fans 1301-1306 through the signal line 190.

Moreover, according to the rotation speed feedback signals TACH<1 . . . 6> of the fans 1301-1306, the state of the first fan controller 140 can be determined. For example, the control unit 200 issues a control signal to turn off the switch Q1. However, the rotation speed feedback signals TACH<1> of the fan 1301 indicates that the fan 1301 is still in a rotation state. In other words, the switch Q1 does no be turned off. This case means that the control unit 200 or the switch Q1 is broken. The first controller 140 is in an abnormally operation state. Moreover, the control unit 200 also can perform a self-detection process. When the control unit 200 can not read the fan control table in a memory unit 201, the control unit 200 is determined to be broken. That is, the first controller 140 is in an abnormally operation state. At this time, the first controller 140 informs the abnormally operation state to the second fan controller 150 through the SGPIO bus 170. Then, the second fan controller 150 gets the right to control the fans 1301-1306. In other words, in this case, the first controller 140 actively informs the second fan controller 150 to get the control right of the fans 1301-1306. In another embodiment, the first controller 140 and the second controller 150 are synchronized through the SGPIO bus 170. Therefore, when the second controller 150 can not get any synchronization signal from the first fan controller 140 through the SGPIO bus 170 in an acquiring, the first fan controller is determined to be broken. Then, the second fan controller 150 gets the right to control the fans 1301-1306.

In view of the above, the server system includes a backup fan controller. When one of the fan controllers is broken, the backup fan controller is triggered to control the fans. Therefore, the thermal damage for the server system is prevented. Moreover, each fan is monitored independently by the current monitor. Therefore, when an over current event happens in a fan, the power supplied to this fan is cut off in real time. At this time, the other fans keep in work. Such fan structure can prevent the thermal damage being spread. On the other hand, a hot-plugging method is used to replace the fan controllers or the fans. Therefore, it is not necessary to power off the server system to replace the fan controllers or fans.

Although the invention has been disclosed with reference to the above embodiments, these embodiments are not intended to limit the invention. It will be apparent to those of skills in the art that various modifications and variations can be made without departing from the spirit and scope of the invention. Therefore, the scope of the invention shall be defined by the appended claims.

What is claimed is:

1. A fan controller for controlling a plurality of fans in a server system according to a fan control signal, the fan controller comprising:
a control unit;
a current monitor coupling with the control unit;
a power supply module transferring power to the fans through a plurality of branch power lines respectively; and
a plurality of current sampling units and a plurality of switches disposed on the branch power lines respectively, the current sampling units coupled with the current monitor and the switches coupled with the control unit;
wherein the control unit switches the switches and the current sampling units sample current signals in the branch power lines respectively, and, when the current monitor monitors one of the current signals being over a threshold value, the current monitor issues an over-current signal to the control unit to turn off the corresponding switch to cut off the power supplied to the corresponding fan by the power supply module.

2. The fan controller of claim 1, wherein the switches are transistors, the source electrodes and the drain electrodes of the transistors are respectively coupled to the branch power lines, and the gate electrodes of the transistors are coupled to the control unit.

3. The fan controller of claim 1, wherein the fans respectively correspond to printed circuit boards, and a plurality of indicator lights are respectively disposed on the printed circuit boards.

4. The fan controller of claim 3, wherein, when one of the fans is broken, the control unit generates a failure signal to turn on a corresponding indicator light.

5. The fan controller of claim 1, wherein the control unit further couples with a thermal unit, and the control unit generates a fan control signal to control the fans according to a real-time temperature of the thermal unit.

6. The fan controller of claim 5, wherein the control unit has a fan control table that records the relationship between temperatures of the thermal unit and set rotation speeds of fans, wherein the control unit gets a set rotation speed according to the real-time temperature of the thermal unit from the fan control table, and the control unit generates the fan control signal according to the set rotation speed.

7. The fan controller of claim 6, wherein the fans generate rotation speed feedback signals to the control unit, and the control unit determines rotation speeds of the fans according to the rotation speed feedback signals, wherein, when a rotation speed of a fan is not equal to a set rotation speed, the fan is determined to be broken.

8. The fan controller of claim 7, wherein, when the control unit still receives the rotation speed feedback signals after the control unit turns off the switches, the fan controller is determined to be broken.

9. The fan controller of claim 6, wherein the control unit further performs a self detection process, and when the control unit can not read the fan control table, the fan controller is determined to be broken.

10. The fan controller of claim 1, wherein the fans receive the fan control signal through a first connector, and the fans receive the power from the power supply module through the second connector.

11. A server system, comprising:
a fan backplate having a plurality of fans;
a server array with a plurality of calculation nodes;
a substrate with a multiplexer, the calculation nodes coupled with the multiplexer; and
a fan controller coupled with the calculation nodes through the multiplexer, the fan controller generating a fan control signal to control rotation speeds of the fans according to real-time temperatures of the calculation nodes, and further comprising:
a control unit;
a current monitor coupling with the control unit;
a power supply module respectively transferring power to the fans through a plurality of branch power lines; and
a plurality of current sampling units and a plurality of switches respectively disposed on the branch power lines, the current sampling units coupled with the current monitor and the switches couple with the control unit;
wherein the control unit switches the switches and the current sampling units sample current signals in the branch power lines respectively, and when the current monitor monitors one of the current signals being over a threshold value, the current monitor issues an over-current signal to the control unit to turn off the corresponding switch to cut off the power supplied to the corresponding fan by the power supply module.

12. The server system of claim 11, wherein the fan backplate further comprises a first connector and a second connector, the fans receive the fan control signal through the first connector, and the fans couple with the power supply module through the second connector.
